(19) United States
(12) Patent Application Publication
(10) Pub. No.: US 2024/0051686 A1
(43) Pub. Date: Feb. 15, 2024

(54) AEROSPACE GRADE SENSING TEXTILE WITH SENSOR TOPOLOGY

(71) Applicant: Massachusetts Institute of Technology, Cambridge, MA (US)

(72) Inventors: Juliana Mae CHERSTON, Somerville, MA (US); Joseph A. PARADISO, Medford, MA (US)

(73) Assignee: Massachusetts Institute of Technology, Cambridge, MA (US)

(21) Appl. No.: 18/447,699

(22) Filed: Aug. 10, 2023

Related U.S. Application Data
(60) Provisional application No. 63/397,151, filed on Aug. 11, 2022.

(51) Int. Cl. B64G 1/68; H10N 30/00; H10N 30/30; D06M 11/83

(52) U.S. Cl. CPC B64G 1/68; H10N 30/1061; H10N 30/302; D06M 11/83; D10B 2401/18

(57) ABSTRACT

Described herein, is a sensing textile for a spacecraft, comprising an aerospace-grade fabric substrate having a surface and one or more sensing fibers coupled to the aerospace-grade fabric substrate, wherein at least a subset of the sensing fibers extends above the surface of the substrate. In some embodiments, the sensing fibers comprises one or more of an impact sensor, a charge sensor, a thermal sensor or radiative surface. Some embodiments, the sensing fibers are configured to form one or more patterned topologies about the surface of the aerospace-grade fabric substrate. In some embodiments, the patterned topologies comprises one or more of a pile, looped pile, waffle, spacer, seersucker, plissé, or an embroidery.

### CROSS REFERENCE SECTION

This application claims benefit of U.S. Application No. 63/397,151 filed on Aug. 11, 2022, which is hereby incorporated herein by reference.

### BACKGROUND

There are several populations of high velocity dust in low earth orbit. Manmade debris comprises objects originating from satellites such as fragmented materials and solid rocket motor dust, traveling at speeds up to roughly 10 km/s. Objects of natural origin (e.g., cosmic dust) refers to grains ranging from nanometer (nm) to micron (μm) that originate from scientific processes both within the solar system and from stellar explosions and can achieve speeds up to roughly 100 km/s.

### SUMMARY

Disclosed herein is a sensing textile for a spacecraft. According to one aspect of the disclosure, the sensing textile comprises an aerospace-grade fabric substrate and one or more sensing fibers coupled to the aerospace-grade fabric substrate. In some embodiments, at least a portion of one of the one or more sensing fibers extends above the surface of the substrate. In some embodiments, the one or more sensing fibers are configured to form one or more patterned topologies about the surface of the aerospace-grade fabric substrate, each of the one or more sensing fibers having a width, a length, and a height. The patterned topology comprises one or more fibers extending above the surface of the substrate and arranged in a pattern (i.e. an intended relationship or arrangement of one or more of the fibers).

According to one aspect of the disclosure, a sensing textile for a spacecraft comprises an aerospace-grade fabric substrate having one or more fiber sensors coupled thereto. In embodiments, the fiber sensors include one or more piezoelectric fibers. In some embodiments, the one or more sensing fibers are configured to form one or more patterned topologies about the surface of the aerospace-grade fabric substrate. The patterned topologies include, but are not limited to, a pile, looped pile, waffle, spacer, seersucker, plissé, or an embroidery.

### DESCRIPTION OF THE SEVERAL VIEWS OF THE DRAWINGS

The manner and process of making and using the disclosed embodiments may be appreciated by reference to the figures of the accompanying drawings. It should be appreciated that the components and structures illustrated in the figures are not necessarily to scale, emphasis instead being placed upon illustrating the principals of the concepts described herein. Like reference numerals designate corresponding parts throughout the different views. Furthermore, embodiments are illustrated by way of example and not limitation in the figures, in which:

FIG. 1 is a top view of a sensing textile (also sometimes referred to herein as a “skin” or “covering”) appropriate for use on an outer surface of a spacecraft or other airborne vehicle;

FIG. 2 is a perspective view of a plasma impact site along the surface of a sensing textile, such as the sensing textile of FIG. 1;

FIG. 3 is a side view of a spacer patterned topology;

FIG. 3A is a side view of a waffle patterned topology;

FIG. 3B is a side view of a looped patterned topology;

FIG. 4 is a perspective view of a sensing textile positioned in a structure;

FIG. 4A is a side view of a sensing textile positioned in a structure with additional layers, such as the sensing textile of FIG. 4;

FIG. 4B is a top view of a sensing textile with sensing fibers configured to form different patterned topologies, such as the sensing textile of FIG. 4; and

FIG. 5 is a side view of a sensing textile affixed to a spacecraft.

### DETAILED DESCRIPTION

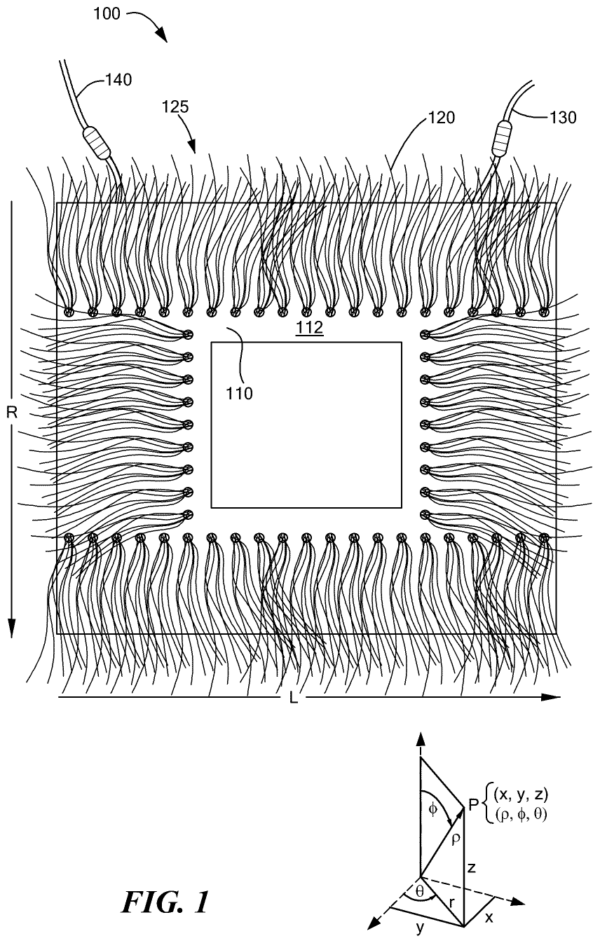

FIG. 1 illustrates an example sensing textile 100 (also sometimes referred to herein as a “skin” or “covering” or a “2.5 D fabric”) appropriate for use on a spacecraft or other airborne vehicle. As used herein, the term sensing textile 100 refers to the combination of a substrate 110 and one or more sensing fibers 120 coupled to the substrate 110. At least a portion of the fibers 120 extend above a surface 112 of the substrate 110. Thus, sensing textile 100 comprises substrate 110 having one or more sensing fibers 120 coupled thereto and is capable of sensing space borne elements and/or particles such as mechanical vibrations induced by hypervelocity impact, properties of plasma (charge, ions, RF signatures) induced by hypervelocity impact, properties of space environment proximate to sensor such as fluctuations in charge, radiation, and temperature, and thermal regulation of spacecraft using unique radiative surfaces.

The sensing textile 100 further comprises a coating on the fibers 120 and the substrate 110. In alternative embodiments, the coating may reside on only the fibers or only the substrate. The characteristics of the coating increase a sensitivity of the fibers 120 by increasing charge plume production when the sensing textile 100 is impacted and thus increase a sensing capability of the fibers 120. Charge plume production refers to the amount of charge released at the site of impact either due to the ionization of the impactor itself, or due to ionization of the target material. Appropriately selected coatings release charge when subject to high velocity impact, and the yielded charge will scale with respect to impact kinematics such as velocity. Therefore, by increasing charge at the collision site, associated charge sensors can detect more minute impact events. The coating may also enhance the fibers mechanical resiliency and may help to reduce (and ideally minimize) internal heating. The coating may comprise one of or a combination of gold or aluminum.

Specifically, gold is shown to produce orders-of-magnitude more charge in comparison to other common space materials. For example, a gold target is expected to produce thirty times more charge compared to a multilayer thermal insulation (MLI) sample. The MLI charge yield at 10 km/s is on the order of 10². In contrast, a charge yield for a goldized sample is expected to be on the order of 3.10³ C/kg.

Further, gold is found to produce between twenty to forty times more charge in the 10 km/s speed regime (30 times the charge relative to MLI sample), and forty five to six hundred times more charge in the 50 km/s speed regime (125 times the charge relative to MLI sample). Accordingly, by coating sensing textile, it is anticipated the benefits for sensing applications of high charge production while preserving the material properties.

Substrate 110 may comprise an aerospace fabric, such as Beta Cloth, ORTHOFABRIC, and/or KEVLAR. Beta cloth is a densely woven, TEFLON-impregnated beta fiberglass fabric sometimes used as an exposed shell layer on persistent space assets and spacesuits. Beta cloth is notable for its resilience to atomic oxygen erosion and other aspects of a harsh space environment (e.g., extended particle and UV radiation, high velocity debris, micrometeoroid impact, and thermal cycling). At 4.3 micron diameter, beta cloth filament yarn may be used to provide a flexible commercially available fiber bundle which may be used to form a fabric (e.g., the Beta cloth). The beta cloth filament yarn can be woven at a density which results in a fiber bundle which may be used to form the beta cloth. Such a weave density may also protect underlying layers (e.g., underlying multilayer insulation coatings) from erosion.

The shape of the substrate 110 may be designed to fit the needs of a particular application such as a skin for a portion of a spacecraft. The substrate 110 may be wrapped or otherwise disposed around a structure (e.g., a frame or other structure or a portion of a spacecraft). The substrate 110 may be shaped to control positioning of one, some, or all of the fibers 120. The substrate 110 may be bent, folded, stretched, etc. to achieve a desired shape suitable to meet the needs of the particular application in which the substrate 110 may be used.

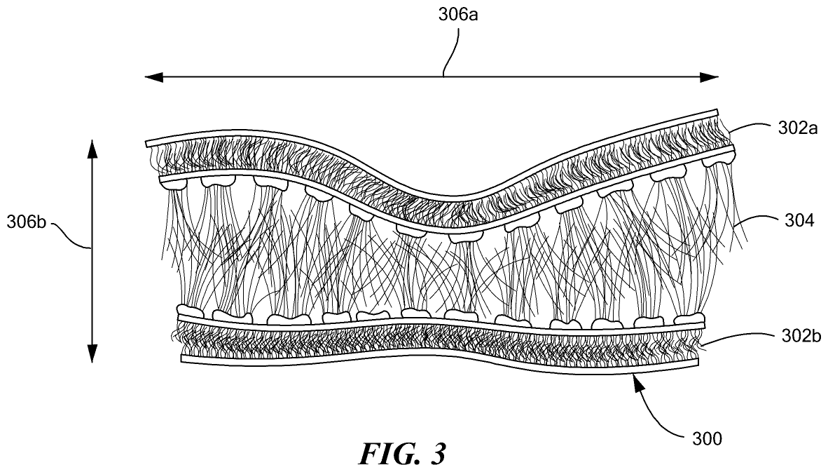

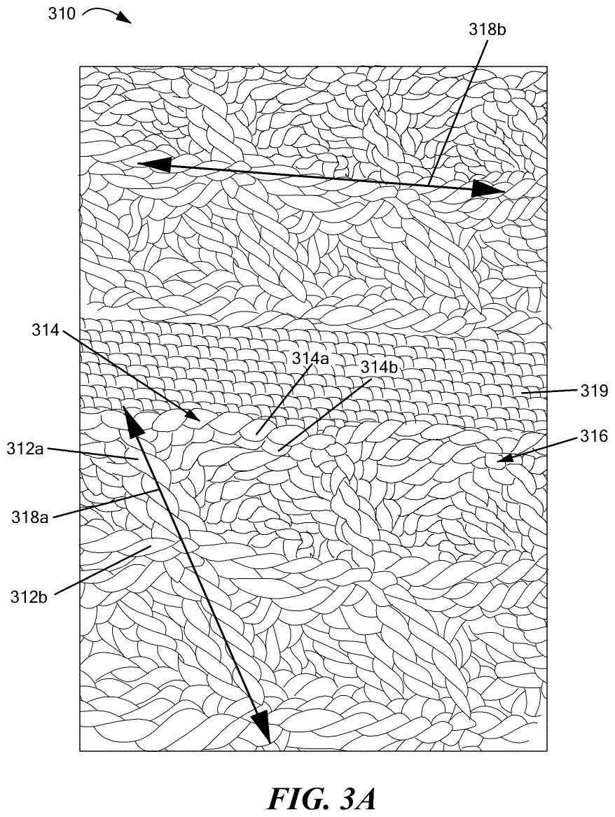

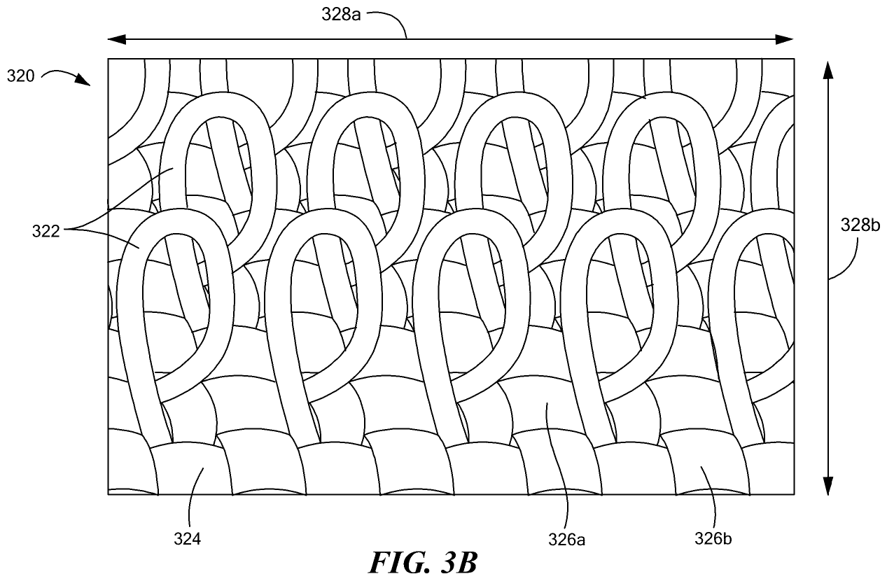

The fibers 120 extend over the surface 112 of the substrate 110. In some embodiments, at least some fibers 120 extend or project from surface 112 of substrate 110. In embodiments, one or more fibers 120 extend or project from surface 112 at an angle φ between 0 degrees and 180 degrees and an angle Θ between 0 degrees and 180 degrees as defined in the coordinate system shown in FIG. 1. The fibers 120 may comprise one or more fibers that are straight or have one or more bends, to form a wavy structure. The fibers 120 may be inserted into, woven into, or otherwise coupled to the substrate 110, such as will be described below in conjunction with FIGS. 3-3B.

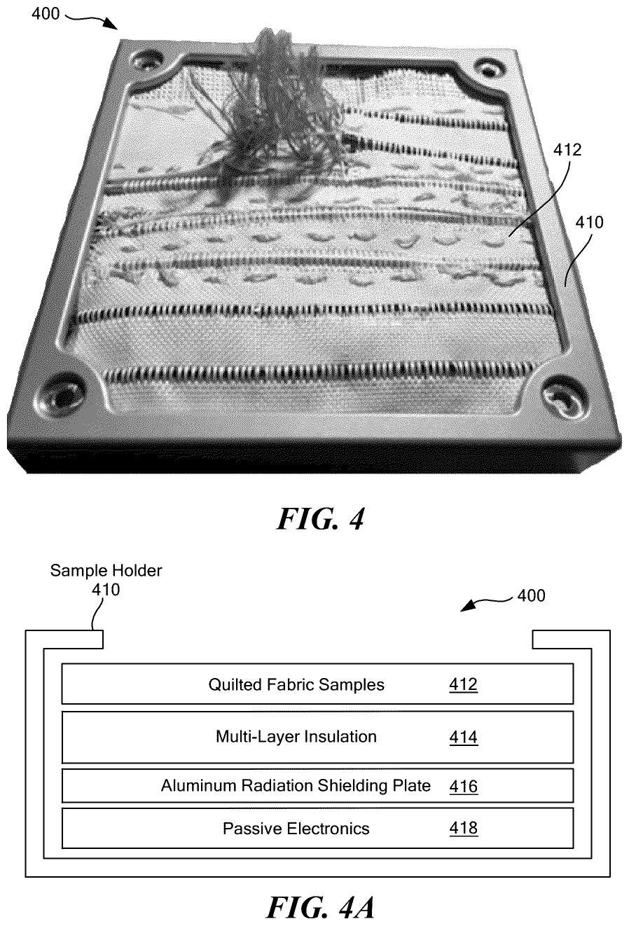

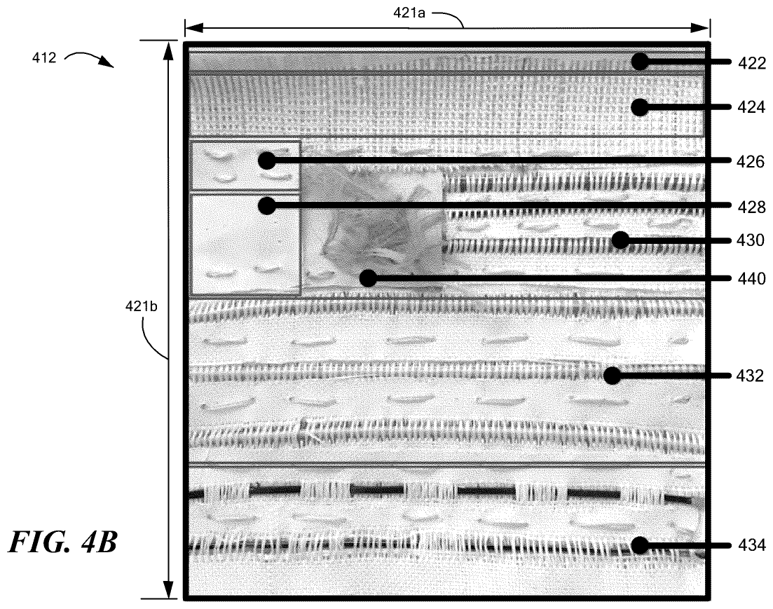

Signal paths 130, 140 may be coupled to the substrate 110. The signal paths 130, 140 may have electrical components coupled thereto or provided as part thereof (e.g., resistors or resistive elements, capacitors or capacitive elements, inductors or inductive elements, wires, etc.). In embodiments (such as those that will be described below in conjunction with FIG. 4), the one or more fiber sensors 120, may comprise or be provided as one or more piezoelectric fibers.

The fibers 120 are configured to form a pattern and a topology selected to enhance sensing and/or detection of space borne elements and/or particles (e.g., space dust, impact plasma charge, temperature, ambient environment charge, radiation, magnetic field). Thus, sensing textile 100 is provided having a “patterned-topology.” A patterned topology comprises one or more fibers 120 extending above the surface 112 of the substrate 110. The one or more fibers 120 are also arranged in a pattern (i.e., an intended interrelationship or arrangement of the one or more fibers 120). Thus, the one or more fibers 120 have a “patterned-topology” and a sensing textile provided in accordance with the concepts described herein may thus be said to have a “patterned-topology.”

As illustrated in FIG. 1, for example, the fibers 120 may be configured to form an electrically conductive pile fabric patterned topology, generally denoted 125 and sometimes referred to as “space fur” or more simply “fur”. Such a pile fabric patterned topology may be useful, for example, to enhance detection of impact plasma charge due to increased surface area and 2.5-dimensional topology extending above the base fabric. Other configurations of the fibers 120 are, of course, also possible. In embodiments, one or more fibers 120 may be configured to form one or more patterned topologies about the substrate (such as will be described below in conjunction with FIGS. 3-3B).

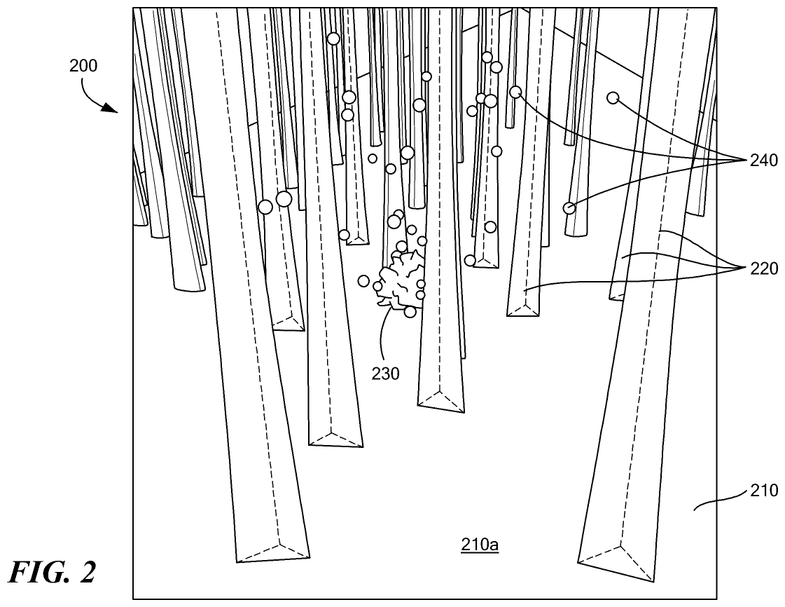

Referring now to FIG. 2, a sensing textile 200 includes a substrate 210 having a surface 210a. Substrate 210 may be the same as or similar to substrate 110 described above in conjunction with FIG. 1. In embodiments, substrate 210 may be provided as a conductive material (e.g., a flat conductor).

One or more sensing fibers 220 are coupled to and extend from (or project from) the substrate 210. The sensing fibers 220 may comprise one or more impact sensors, charge sensors, or thermal sensors and radiative surfaces related to thermal management. For instance, either a thermal sensor, sometimes referred to herein as a thermal management sensor, or radiative surface, sometimes referred to herein as a thermal management radiator. The sensing fibers 220 may comprise piezoelectric fibers, conductive fibers, or electrically conductive fibers with active chips mounted thereon (e.g., at an end or a tip thereof).

As illustrated in FIG. 2, a plasma or plasma particle 231 impacts sensing textile 200 at an impact site 230 on or about surface 210a of substrate 210. The impact of plasma particles 231 generates plasma charge emissions, generally denoted 240. Plasma charge emissions 240 contact one or more of sensing fibers 220, which collectively form a pile fabric patterned-topology. It can thus be seen that one benefit of using a pile fabric patterned topology is that such a patterned topology increases the surface area of the sensing textile 200 for collecting charge in a given “footprint” (i.e., in a sensor having a given area (a given length and width) or a given volume (a given length, width and height)).

By increasing (and in some cases, significantly increasing) a surface area by arranging fiber sensors in a pile fabric patterned topology (examples of which are shown in FIGS. 1 and 2), a sensing textile 200 has a sensitivity which is greater than a sensitivity which may be achieved by prior art approaches. For example, a sensing textile 200 comprising fiber sensors in a pile fabric patterned topology has a sensitivity which is greater than a sensitivity which may be achieved by sensors comprising single-wire or planar conductor substrates.

Impactors can result in local deformation, including cratering, on the of the surface 210a of the substrate 210 at the impact site 230. The resulting transverse wave propagation, which may carry and further spread the impactor, is carried at least partially by individual sensing fibers 220, and appears to slow and spread following the impact. The propagation speed of the wave can be coarsely measured. As an example taken from ground testing in low impactor velocity regimes. Ground testing at ultra-high velocity regimes (10's of km/s) demonstrated elevated sensitivity of pile fabric to impact plasma in comparison to flat conductive fabric targets In embodiments, chip-scale imagers may be mounted at ends (or tips) of some sensing fibers 220. In such embodiments, the sensing textile 200 may serve as a means to optically image without requiring a secondary camera.

The sensing fibers 220 provide an increased surface area and unique geometry capable of enhancing the technical functionality of the sensing fibers 220. The increased surface area is substantially greater compared to a conventional planar fabric, which can increase sensitivity and the ability to radiate charge. The fibers have the advantage of maximal surface area and tightly controlled sparsity. The geometry of the sensing fibers 220 can allow for enhanced sensing, such as sensing of phenomena proximate to the substrate 210. Accordingly, the sensing fibers 220 may be configured to form one or more patterned topologies about the surface in order to enhance and/or control the sensing abilities of the sensing fibers 220. It should be appreciated that in embodiments, at least one, but not necessarily all of the fibers shown in FIGS. 1 and 2 may be sensing fibers.

That is sensing textiles 100 (FIG. 1) and 200 (FIG. 2) may comprise fibers which provide structural support and do not have a sensing function. Furthermore, it should be appreciated that in some embodiments, different versions of the sensing fibers may perform different sensing functions (i.e., it is not necessary that all sensing fibers in a sensing textile perform the same sensing function).

FIGS. 3-3B disclose possible patterned topologies of the sensing textile which may be formed via one or more sensing fibers such as the sensing fibers described above in conjunction with FIGS. 1 and 2. The patterned topology refers to the extension of one or more of the fibers over the surface of the substrate and arranged in a pattern (i.e. an intended relationship or arrangement of the one or more fibers). In general overview, the sensing fibers may extend in many different directions (e.g., in a lateral direction, along a length of the fiber, and in the longitudinal direction, along a width of the fibers). The fibers may be configured along the different directions to form one or more patterned topologies about the surface of an aerospace-grade fabric substrate, which will be described below.

One possible patterned topology which may be formed via a configuration of the sensing fibers, such as the sensing fibers described above in conjunction with FIGS. 1 and 2, is a woven fabric. Woven fabrics incorporate weft and warp fibers wherein the warp fibers are arranged around the weft fibers. Pores are formed in the space between the weft and warp fibers. Given the arrangement of the weft and warp fibers, the pore structure will differ. Other factors that impact the pore structure include the structure of the substrate, the shaping of the substrate, the size of the fibers, etc. Such woven fabrics may have a lateral axis in line with the lateral axis of the substrate and a longitudinal axis perpendicular to the lateral axis of the substrate. Accordingly, the weft fibers are aligned along a lateral axis, while the warp fibers move along the longitudinal axis. Weft insertion in a plain-weave helps to reduce (and ideally minimize) buckling from e.g. thermal strain relative to other weave patterns. Different patterned topologies may incorporate different warp and weft arrangements.

Two examples of a woven fabric are 2D fabrics and 2.5D fabrics. 2D fabrics comprise two dimensional, or so called “flat”, fabric (either woven or knitted). For example, incorporate a so-called “plain weave”, wherein the warp and weft fibers are arranged perpendicular to each other, and the layers are separate without any adjoining warp or weft fibers. Accordingly, each layer forms a “flat” two dimensional fabric.

In contrast, 2.5D fabrics include one or more sensing fibers coupled to and extending above or below the surface of the fabric or other so-called patterned topologies integrated above or below the surface of the fabric. For example, in a 2.5D fabric the weft fibers may extend along the lateral axis, while the warp fibers extend in the longitudinal axis around weft fibers above or below the previous weft fiber. Meaning the warp fibers are arranged around weft fibers not in line with the previous weft fiber. The arrangement of the warp fibers around the weft fibers indicates the warp fibers may be one, two, or more layers above or below the location of the weft fiber. The arrangement of warp fibers interconnects the layers of fibers in the 2.5D fabric. The weft fibers may be cut or otherwise terminate such that they extend above or below the longitudinal axis, and accordingly they extend above or below the weft fibers, to form a 2.5D fabric or another patterned topology.

Other patterned topologies may be possible by other configurations of the warp and weft fibers. The patterned topologies may comprise a pile (or cut pile) patterned topology, a looped pile patterned topology, a waffle patterned topology, a spacer patterned topology, a seersucker patterned topology, a plissé patterned topology, or an embroidery. In the seersucker patterned topology, the woven patterned topology forms a surface consisting of puckered and flat sections, wherein either the weft or warp fibers are textured, and the opposing fibers are flat. A plissé patterned topology refers to a patterned topology wherein both the weft and warp fibers are textured. Said textured fibers refers to a crinkled surface, which form ridges or stripes. An embroidery refers to a patterned topology that has an additional fiber woven into the weaving of warp and weft fibers. Accordingly, an embroidered patterned topology may include one or more patterned topologies, wherein one or more additional fibers is embedded into the warp or weft fibers to form an additional interwoven texture atop the patterned topology.

The fibers may be coupled to the substrate in a number of different ways. For example, the fibers may be inserted into, woven into, or otherwise coupled to the warp and weft arrangements. The fibers may be extensions of the warp and weft fibers, or the warp and weft fibers may be cut in order to form the extension. For example, pile fabric patterned topology is produced by stitching loops into a base fabric using a fiber, securing the loops in place, cutting the loops, and then brushing the fibers out into individual fibers extending from the surface of the substrate.

FIG. 3 discloses a spacer patterned topology 300. A first backing layer 302a is separated from (or spaced apart from) a second backing layer 302b by one or more sensing fibers 304. The backing layers 302a, 302b are parallel along the lateral axis 306a and may be formed from sensing fibers. The fibers 304 are parallel to the longitudinal axis 306b and perpendicular to the lateral axis 306a. The fibers 304 may comprise one or more fibers between the two backing layers 302a, 302b. The fibers 304 may twist together along the longitudinal axis 306b forming an interwoven structure between the two backing layers 302a, 302b.

FIG. 3A discloses a waffle patterned topology 310, wherein one or more sensing weft fibers 312a is arranged along a lateral axis 318a and one or more sensing warp fibers 312b is arranged along a longitudinal axis 318b. The fibers 312a, 312b are arranged next to and cross over one another, forming a first rectangle 314a. Additional weft and warp fibers are arranged similarly, but form a second rectangle 314b adjacent to and smaller than the first rectangle 314a. Additional fibers are arranged similarly, but form increasingly smaller rectangles adjacent to the rectangles 314a, 314b to form a first waffle structure 314.

Multiple waffle structures may be arranged next to each other, for example a second waffle structure 316 may be arranged next to the first waffle structure 314. The second waffle structure 316 may be formed using the same or different warp fibers 312b and weft fibers 312a. The waffle structures 314, 316 may be arranged next to a different patterned topology 319, to form a support or a side of the waffle patterned topology 310. The fibers 312a, 312b may be twisted or otherwise textured. The fibers 312a, 312b may be a different texture than the different patterned topology 319.

FIG. 3B discloses a looped patterned topology 320. A backing 324 is formed from one or more sensing fibers 326a, 326b. The one or more sensing fibers in the backing 324 may comprise sensing weft fibers 326a that extend along the lateral axis 328a and sensing warp fibers 326b that extend along the longitudinal axis 328b.

Looped fibers 322 are coupled to and extend from the backing 324. The looped fibers 322 may comprise fibers bent such that they leave the backing 324 and return to the backing 324 by making an arch shape. The looped fibers 322 may return to the same location in the backing they left or may return to the backing 324 in another location. The looped fibers 322 may be extensions of the fibers 326a, 326b that make up the backing. The looped fibers may be bent as to make an arch, semi-circle, oblong, or other shapes.

The looped fibers 322 may be interwoven, to form knots. A warp fiber 326b may be tied one or more times around one or more weft fibers 326a to form a knot. The looped pattern patterned topology may be made up entirely of one type of fiber bend or a mixing of fiber shapes, knots, etc. The fiber bend or knot may be identical in size or may alternative in size. One or more of the looped fibers 322 may be the same shape, or they may alternate in shape. The spacing between the looped fibers along the longitudinal axis 328b or the lateral axis 328a may be identical or alternative in size along the backing. The looped fibers may be cut in order to form straight fibers that extend from the backing, this may be referred to as a “pile” or a “cut pile”, as described above.

FIGS. 4-4B illustrate a sensing textile 412 disposed in (or positioned in or coupled to) a structure 410 (e.g., a frame, backing, or sample holder). Sensing textile 412, may comprise one or more sensing fibers such as the sensing fibers described above in conjunction with FIGS. 1, 2, and 3-3B. The structure 410 supports the sensing textile 412. Additional layers may be positioned in the structure 410 and may be used to further support the sensing textile 412 in an aerospace or other airborne vehicle context.

FIG. 4A discloses a side view of example embodiment 400 of the sensing textile 412 of FIG. 4. The example embodiment 400 includes the sensing textile 412 positioned in the structure 410 along with additional layers 414, 416, 418. The additional layers include a multilayer insulation 414 positioned below the sensing textile 412. A radiation shield plate 416 may be positioned below the insulation 414 and may comprise aluminum. Passive electronics 418 may be positioned below the plate 416. Additional layers may be included beyond those mentioned above.

FIG. 4B discloses a top view of the sensing textile 412 disclosed in FIG. 4, with a plurality of sensing fibers configured to form a plurality of different patterned topologies atop the surface of the sensing textile 412. The sensing textile 412 has a length 421a along the lateral axis and a width 421b along the longitudinal axis, wherein the length 421a may be the same as or different than the width 421b. Across the length 421a the same patterned topology is formed, conversely across the width 421b a plurality of different patterned topologies are formed.

As demonstrated by the sensing textile 412 shown in FIG. 4B, a plurality of different patterned topologies are formed from the plurality of sensing fibers atop the sensing textile 412. The different patterned topologies include: a control element 422, such as a KAPTON film; a beta yarn and liberator conductive yarn weave 424; a first control sample fabric 426, such as a TEFLON impregnated beta cloth simulant; a second control sample fabric 428, such as a NASA beta cloth; a piezoelectric sensor variant 430; a conductive pile patterned topology 440; a TEFLON coated beta cloth simulant with three piezoelectric fibers 432; and a beta with two piezoelectric fibers 434.

The piezoelectric fibers 434 may be manufactured by removing the core from commercial piezoelectric cables and coating the cables with elastomeric conductive ink, or directly pulled, as has been demonstrated by various researchers. The piezoelectric fibers 434 are then woven into the sensing textile 412. The piezoelectric fibers 434 exhibit a transverse energy propagation that allows a fabric with sparsely weft-inserted sensing fibers to function as a sensor. The resulting fabric is shown to preserve sufficient material robustness properties including: high thermal emissivity; tolerance to thermal cycling; low atomic oxygen and radiation degradation; and capacity to sense sub mm-scale impactors.

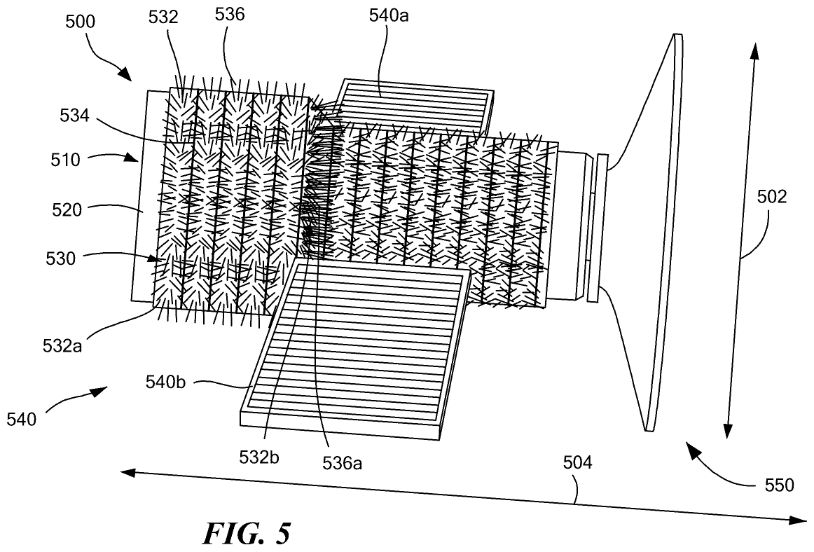

FIG. 5 discloses an exemplary spacecraft 500 including a sensing textile 530 affixed to a spacecraft 510. The spacecraft 510 includes: one or more solar panels 540a, 540b; additional electrical components 550 (e.g. a radar, an antenna); and a body 520. The sensing textile 530 is affixed to the body 520 of the spacecraft 510. The sensing textile 530 is affixed to the body 520 such that it forms a cohesive cover along the body 520 of the spacecraft 510. In some embodiments, the sensing textile 530 may be affixed to the entire body or to a portion of the body.

The sensing textile 530 includes a substrate 532 comprising piezoelectric fibers 534, which includes one or more piezoelectric fibers such as those described above in conjunction with FIG. 4-4B. The piezoelectric fibers 534 are configured to be parallel to a length 504 and perpendicular to a width 502 of the spacecraft 500. In some embodiments, the piezoelectric fibers 534 are configured to be parallel to the width 502 and perpendicular to the length 504 of the spacecraft 500.

Sensing fibers 536, which includes one or more sensing fibers such as the sensing fibers described above in conjunction with FIGS. 1 and 2, are coupled to and extend from a surface 532a of the substrate 532. The sensing fibers 536 extend to form a pile patterned topology, such as the pile patterned topology described above in conjunction with FIGS. 3-3B, extending outwards from the substrate and ultimately from the body 520 of the spacecraft 510.

The spacecraft 510 is shaped such that there is a bend along the surface of the body 520 of the spacecraft 510. The bend creates a bend 532b along the surface of the sensing textile 530. The sensing fibers 536a attached to the substrate 532 along the bend 532b extend in accordance with the bend 532b, accordingly the sensing fibers 536a attached to the substrate along the bend 536b extend along the length 504 while the sensing fibers 536 not attached at the bend extend along the width 502 of the spacecraft 500. Following, the direction of the sensing fibers 536a is adjusted by the location along the substrate 532.

Although reference is made herein to particular materials, it is appreciated that other materials having similar functional and/or structural properties may be substituted where appropriate, and that a person having ordinary skill in the art would understand how to select such materials and incorporate them into embodiments of the concepts, techniques, and structures set forth herein without deviating from the scope of those teachings.

Various embodiments of the concepts, systems, devices, structures and techniques sought to be protected are described herein with reference to the related drawings. Alternative embodiments can be devised without departing from the scope of the concepts, systems, devices, structures and techniques described herein. It is noted that various connections and positional relationships (e.g., over, below, adjacent, etc.) are set forth between elements in the following description and in the drawings. These connections and/or positional relationships, unless specified otherwise, can be direct or indirect, and the described concepts, systems, devices, structures and techniques are not intended to be limiting in this respect. Accordingly, a coupling of entities can refer to either a direct or an indirect coupling, and a positional relationship between entities can be a direct or indirect positional relationship.

As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising, “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance, or illustration. Any embodiment or design described herein as “exemplary” is not necessarily to be construed as preferred or advantageous over other embodiments or designs. The terms “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection.”

References in the specification to “one embodiment, “an embodiment,” “an example embodiment,” etc., indicate that the embodiment described can include a particular feature, structure, or characteristic, but every embodiment can include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal, “top,” “bottom,” and derivatives thereof shall relate to the described structures and methods, as oriented in the drawing figures. The terms “overlying,” “atop,” “on top, “positioned on” or “positioned atop” mean that a first element, such as a first structure, is present on a second element, such as a second structure, where intervening elements such as an interface structure can be present between the first element and the second element. The term “direct contact” means that a first element, such as a first structure, and a second element, such as a second structure, are connected without any intermediary elements.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

The terms “approximately” and “about” may be used to mean within ±20% of a target value in some embodiments, within ±10% of a target value in some embodiments, within ±5% of a target value in some embodiments, and yet within ±2% of a target value in some embodiments. The terms “approximately” and “about” may include the target value. The term “substantially equal” may be used to refer to values that are within ±20% of one another in some embodiments, within ±10% of one another in some embodiments, within ±5% of one another in some embodiments, and yet within ±2% of one another in some embodiments.

The term “substantially” may be used to refer to values that are within ±20% of a comparative measure in some embodiments, within ±10% in some embodiments, within ±5% in some embodiments, and yet within ±2% in some embodiments. For example, a first direction that is “substantially” perpendicular to a second direction may refer to a first direction that is within ±20% of making a 90° angle with the second direction in some embodiments, within ±10% of making a 90° angle with the second direction in some embodiments, within ±5% of making a 90° angle with the second direction in some embodiments, and yet within ±2% of making a 90° angle with the second direction in some embodiments.

It is to be understood that the disclosed subject matter is not limited in its application to the details of construction and to the arrangements of the components set forth in the following description or illustrated in the drawings. The disclosed subject matter is capable of other embodiments and of being practiced and carried out in various ways. Also, it is to be understood that the phraseology and terminology employed herein are for the purpose of description and should not be regarded as limiting. As such, those skilled in the art will appreciate that the conception, upon which this disclosure is based, may readily be utilized as a basis for the designing of other structures, methods, and systems for carrying out the several purposes of the disclosed subject matter. Therefore, the claims should be regarded as including such equivalent constructions insofar as they do not depart from the spirit and scope of the disclosed subject matter.

Although the disclosed subject matter has been described and illustrated in the foregoing exemplary embodiments, it is understood that the present disclosure has been made only by way of example, and that numerous changes in the details of implementation of the disclosed subject matter may be made without departing from the spirit and scope of the disclosed subject matter.

What is claimed is:

1. A sensing textile for a space craft, comprising:
an aerospace-grade fabric substrate having a surface; and
one or more sensing fibers coupled to the aerospace-grade fabric substrate, wherein at least a portion of one of the one or more sensing fibers extends above or below the surface of the substrate.

2. The sensing textile for a space craft of claim 1, wherein one or more of the sensing fibers comprises one or more of an impact sensor, a charge sensor, a thermal sensor or radiative surface.

3. The sensing textile for a space craft of claim 1, wherein the aerospace-grade fabric substrate further comprises one or more fiber sensors, wherein the fiber sensors are a piezoelectric fiber.

4. The sensing textile for a space craft of claim 1, wherein one or more of the sensing fibers are positioned at an angle compared to the surface of the aerospace-grade fabric substrate.

5. The sensing textile for a space craft of claim 4, wherein one or more of the sensing fibers are straight or bent.

6. The sensing textile for a space craft of claim 1, wherein one or more of the sensing fibers are configured to form one or more patterned topologies about the surface of the aerospace-grade fabric substrate.

7. The sensing textile for a space craft of claim 6, wherein the one or more patterned topologies comprises one or more of a pile, looped pile, waffle, spacer, seersucker, plissé, or an embroidery.

8. The sensing textile for a space craft of claim 1, further comprising a coating disposed over at least a portion of one or more of the one or more sensing fibers to increase a sensing capability of the one or more sensing fibers.

9. The sensing textile for a space craft of claim 8, wherein the coating comprises one of: gold; or aluminum.

10. A sensing textile for a space craft, comprising:
an aerospace-grade fabric substrate having a surface; and
one or more sensing fibers having a width, a length, and a height, coupled to the aerospace-grade fabric substrate, wherein the one or more sensing fibers are disposed about the surface of the aerospace-grade fabric substrate to form one or more patterned topologies.

11. The sensing textile for a space craft of claim 10, wherein one or more of the sensing fibers comprises one or more of an impact sensor, a charge sensor, a thermal sensor or radiative surface.

12. The sensing textile for a space craft of claim 10, wherein the aerospace-grade fabric substrate further comprises one or more fiber sensors, wherein the fiber sensors are a piezoelectric fiber.

13. The sensing textile for a space craft of claim 10, wherein one or more of the sensing fibers extends in a lateral direction along the length of the sensing fibers, one or more of the sensing fibers extends in a longitudinal direction along the width of the sensing fibers, wherein the one or more of the sensing fibers extending in a longitudinal direction is configured to move along the longitudinal direction to form a woven configuration.

14. The sensing textile for a space craft of claim 10, wherein the one or more patterned topologies comprises one or more of a pile, looped pile, waffle, spacer, seersucker, plissé, or an embroidery.

15. The sensing textile for a space craft of claim 10, further comprising a coating, wherein the coating is configured to increase a sensing capability of the sensing fibers by increasing a sensitivity of the sensing fibers, wherein the coating comprises one of gold or aluminum.

16. A sensing textile for a space craft, comprising:
an aerospace-grade fabric substrate having a surface, wherein the aerospace-grade fabric substrate is coupled to one or more fiber sensors, wherein the fiber sensors are a piezoelectric fiber; and
one or more sensing fibers coupled to the aerospace-grade fabric substrate, wherein the one or more sensing fibers are configured to form one or more patterned topologies about the surface of the aerospace-grade fabric substrate.

17. The sensing textile for a space craft of claim 16, wherein the one or more sensing fibers comprises one or more of an impact sensor, a charge sensor, a thermal sensor or radiative surface.

18. The sensing textile for a space craft of claim 16, wherein the one or more patterned topologies comprises one or more of a pile, looped pile, waffle, spacer, seersucker, plissé, or an embroidery.

19. The sensing textile for a space craft of claim 16, further comprising a coating, wherein the coating is configured to increase a sensing capability of by increasing a sensitivity of the sensing fibers, wherein the coating comprises one of gold or aluminum.
